(19) United States
(12) Patent Application Publication
(10) Pub. No.: US 2007/0285694 A1
(43) Pub. Date: Dec. 13, 2007

(54) Color conversion definition creation apparatus and color conversion definition creation program storage medium

(75) Inventor: Shuhei Horita, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Minato-ku (JP)

(21) Appl. No.: 11/806,903

(22) Filed: Jun. 5, 2007

(30) Foreign Application Priority Data
Jun. 8, 2006 (JP) 2006-159775

(51) Int. Cl. G03F 3/08

(52) U.S. Cl. 358/1.9; 358/518

(57) ABSTRACT

A color conversion definition creation apparatus has an acquisition section that acquires a XYZ value by colorimetry for a color patch with the color represented by a representative reference lattice point out of reference lattice points each having four reference coordinate components on the K axis, among plural lattice points arranged regularly within a CMYKRG color space. The apparatus further has: a calculation section that calculates XYZ values made for other reference lattice points having the reference coordinate components, based on correspondence between the XYZ value acquired by the acquisition section and the representative reference lattice point corresponding to the XYZ value; and an interpolation section that obtains XYZ values made for other lattice points except for the reference lattice points among the above lattice points, by interpolation based on correspondence between the reference lattice points and the XYZ values corresponding to the reference lattice points.

### BACKGROUND OF THE INVENTION

1. Field of the Invention

The present invention relates to a color conversion definition creation apparatus that creates a color conversion definition defining the color conversion between a first color space and a second color space, and a storage medium storing a color conversion definition creation program that causes a computer to operate as the color conversion definition creation apparatus.

2. Description of the Related Art

Various types of input devices that input some manuscript to obtain image data, such as a color scanner that reads a recorded image to obtain image data or a DSC (digital still camera) that forms and reads an image of a subject on a solid state image pickup device to obtain image data, for example, are well known. These input devices produce image data of which image colors are represented in combination of three color component values of R (red), G (green) and B (blue), for example. At this time, a color space (e.g., RGB color space) having a coordinate axis corresponding to each component value for this image data depends on an input device from which the image data is obtained.

Also, various types of output devices that output an image based on image data are well known, including a photo printer that records an image on a sheet of photographic paper by developing the photographic paper after exposure to laser light, a printer that records an image on a sheet of paper by an electrophotography or ink-jet method, a printing press that produces a large amount of printed matter by rotating a rotary press, and an image display device such as a CRT display or plasma display that displays an image on a display screen based on image data. These output devices output a color image, based on image data of which image colors are represented in combination of component values of three colors of RGB, or combination of component values of four colors of C (cyan), M (magenta), Y (yellow) and K (black). A color space (e.g., RGB color space or CMYK color space) having a coordinate axis corresponding to each component value for image data treated by an output device depends on the output device that outputs an image based on the image data.

Generally, an input device and an output device have mutually different color spaces corresponding to the treated image data. Therefore, for example, even if both the input device and the output device treat the image data of which image colors are represented in combination of component values of three colors of RGB, the original image colors inputted by the input device and the image colors outputted by the output device are typically unmatched, when the output device outputs the image directly using the image data obtained by the input device. Accordingly, when the input device reads a manuscript to obtain image data and the output device reproduces a manuscript based on the image data, the image data obtained by the input device is not directly sent to the output device, but is required to convert before sending. Herein, the image data is converted in view of the image color, and this conversion of image data is referred to color conversion. Also, an LUT (lookup table) defining the correlation of image data before and after the color conversion is referred to as color conversion definition.

For example, when an image based on image data of which colors are represented in a RGB color space obtained by an input device is outputted by an output device that represents colors by color materials of four colors of CMYK, a color conversion definition defining the color conversion between the RGB color space depending on the input device and the CMYK color space depending on the output device is employed. And the image data with the colors represented in the RGB color space is converted into the image data with the colors represented in the CMYK color space through the color conversion using this color conversion definition.

Herein, usually, the color conversion is conceptually made via a common color space that is a device-independent color space, such as a Lab color space or XYZ color space, for example. Therefore, the color conversion definition is also conceptually a combination of: an input-side color conversion definition defining the color conversion between the color space depending on the input device (input color space) and the common color space; and an output-side color conversion definition defining the color definition between the color space depending on the output device (output color space) and the common color space.

By the way, the color conversion definition defining the color conversion between the device-dependent color space (device color space) such as input color space or output color space and the common color space is generally created by obtaining plural coincidence points on the common color space corresponding via the color conversion to plural lattice points arranged regularly on the device color space.

Generally, in creating the color conversion definition, some of plural lattice points are selected as representative points, and plural color patches of which colors are represented at the coordinate of each representative point are prepared, thereby the calorimetric value such as Lab value or XYZ value is acquired by making colorimetry for each color patch. This calorimetric value is equivalent to the coordinate in the common color space such as Lab color space or XYZ color space, and the coordinate is equivalent to the coordinate of coincidence point corresponding to the representative point on the device color space via the color conversion. Next, the coincidence point corresponding to the lattice point other than the representative point is calculated based on the coincidence point corresponding to the representative point. For example, there is proposed a calculation method for calculating the coincidence point corresponding to the lattice point other than the representative point by solving a unified equation prescribing the correlation between coincidence points on the common color space corresponding to the lattice points and the lattice points on the device color space, with the correspondence between the representative point and the coincidence point as a boundary condition (e.g., refer to Japanese Patent Laid-Open No. 2006-24971).

Thereby, the coincidence points on the common color space are obtained for all the lattice points on the device color space, thereby the color conversion definition defining the color conversion is created by the pair of each lattice point and each coincidence point.

Also, with the method of Japanese Patent Laid-Open No. 2006-24971, as the number of correspondences between the representative point and the coincidence point serving as the boundary condition is larger, that is, the number of color patches of colorimetry object is larger, the coincidence point corresponding to the lattice point other than the representative point is calculated at higher precision, so that the color conversion definition has higher precision.

By the way, in recent years, to appropriately represent colors that can not be represented by only process colors, in addition to four colors of CMYK (process colors), in the output device such as a printer or printing press, the colors (special colors) such as R color, G color and B color other than the process colors have been used. When such special colors are used, the dimension of the device color space is higher than where only the process colors are used, resulting in a very large number of lattice points on the device color space. In addition, when such special colors are used, the number of lattice points is very large, thereby a very large number of color patches are needed to create the color conversion definition at high precision.

### SUMMARY OF THE INVENTION

The present invention has been made in view of the above circumstances and provides a color conversion definition creation apparatus that can create the color conversion definition at high precision by suppressing the number of color patches of colorimetry object, and a storage medium storing a color conversion definition creation program that causes the computer to operate as such color conversion definition creation apparatus.

According to the present invention, there is provided a color conversion definition creation apparatus that creates a color conversion definition defining a color conversion between a first color space and a second color space, including:

an acquisition section that acquires a coincidence point on the second color space corresponding via the color conversion to a predetermined representative reference lattice point, among reference lattice points each having a predetermined reference coordinate component out of plural coordinate components, among plural lattice points arranged regularly in the first color space and having any of the plural coordinate components along a predetermined coordinate axis;

a calculation section that calculates coincidence points on the second color space corresponding via the color conversion to other reference lattice points each having the same reference coordinate component as the reference coordinate component of the representative reference lattice point to which the coincidence point acquired by the acquisition section corresponds, based on correspondence between the coincidence point acquired by the acquisition section and the representative reference lattice point to which the coincidence point corresponds; and

an interpolation section that calculates coincidence points on the second color space corresponding via the color conversion to other lattice points except for the reference lattice points among the lattice points, by interpolation based on correspondence between the reference lattice point and the coincidence point corresponding to the reference lattice point.

With the color conversion definition creation apparatus of the invention, some of plural unknown coincidence points other than the known coincidence points acquired by the acquisition section are calculated by using the known coincidence points acquired by the acquisition section as a clue by the calculation section, and the remaining coincidence points are interpolated by the interpolation section by using the calculation results as a clue, thereby performing a two-stage process. Herein, the coincidence point obtained by the calculation section is calculated by treating only some of the unknown coincidence points as the calculation object, and has higher precision than where all the unknown coincidence points are calculated at a time by use of the known coincidence points as a clue. Further, in the interpolation section, the remaining coincidence points are interpolated by use of the coincidence points calculated at high precision as a clue, and also has higher precision than where all the unknown coincidence points are calculated at a time. In this manner, with the color conversion definition creation apparatus of the invention, if the number of clues is the same, all the unknown coincidence points can be obtained at higher precision. In other words, with the color conversion definition creation apparatus of the invention, the color conversion definition at high precision equivalent to that of the color conversion definition created by obtaining all the unknown coincidence points using a number of clues can be created based on a smaller number of clues through this two-stage process. Herein, if the known coincidence points acquired by the acquisition section as the clues are obtained by making the colorimetry for plural color patches of which colors are represented by the representative reference lattice points, the color conversion definition creation apparatus of the invention can create the color conversion definition at high precision by suppressing the number of color patches.

Herein, preferably, in the color conversion definition creation apparatus of the invention, the calculation section calculates the coincidence point corresponding to the reference lattice point by solving a Laplace equation stipulating systematically a correlation between the reference lattice points and the coincidence points corresponding to the reference lattice points, by using the correspondence between the coincidence point acquired by the acquisition section and the representative reference lattice point to which the coincidence point corresponds as a boundary condition.

With this preferable feature of the color conversion definition creation apparatus, since the coincidence points corresponding to the reference lattice points are calculated smoothly continuously on the second color space by solving the Laplace equation representing an equilibrium condition in the field of physical quantities, the color conversion definition is obtained by excellently avoiding the discontinuous gradation in the color conversion.

Also, preferably, in the color conversion definition creation apparatus of the invention, the interpolation section is given a non-linearity of interpolation and calculates the coincidence points corresponding to the other lattice points by nonlinear interpolation in accordance with the non-linearity.

With this preferable feature of the color conversion definition creation apparatus, the coincidence point is obtained by nonlinear interpolation, thereby the color conversion definition can be created at higher precision by reflecting the nonlinear output characteristic of the output device such as a printing press, for example.

Also, preferably, in the color conversion definition creation apparatus of the invention, the first color space is a color space having a coordinate axis corresponding to K color as the predetermined coordinate axis.

The K color is achromatic color, and different at the same level from any other chromatic color. Therefore, with the preferred form of the color conversion definition creation apparatus, the coordinate axis corresponding to the K color is made the predetermined coordinate axis, thereby the calculation and interpolation can be performed at higher precision by suppressing a disorder in the balance of colors other than the K color.

Also, preferably, the color conversion definition creation apparatus of the invention further includes a nonlinear calculation section that calculates a non-linearity of interpolation based on the coincidence point acquired by the acquisition section,

wherein the interpolation section is given the non-linearity calculated by the nonlinear calculation section, and calculates the coincidence points corresponding to the other lattice points by nonlinear interpolation in accordance with the non-linearity.

With this preferable feature of the color conversion definition creation apparatus, the nonlinear output characteristic of the output device, for example, can be reflected to the interpolation.

Also, preferably, in the color conversion definition creation apparatus of the invention, the second color space is a XYZ color space, and

the color conversion definition creation apparatus further includes a conversion section that converts the coordinates of the coincidence points on the XYZ color space corresponding to the lattice points via the color conversion defined by the color conversion definition into coordinates on a Lab color space, thereby converting the color conversion definition to a color conversion definition defining a color conversion between the first color space and the Lab color space.

With this preferable feature of the color conversion definition creation apparatus, first of all, the color conversion definition is created using the XYZ color space often treated as the calorimetric color space by the calorimeter or the like, and the created color conversion definition is converted, thereby the color conversion definition using the Lab color space which the person is likely to image can be easily obtained.

According to the invention, there is provided a storage medium storing a color conversion definition creation program that is incorporated into a computer and causes the computer to operate as a color conversion definition creation apparatus that creates a color conversion definition defining a color conversion between a first color space and a second color space, the color conversion definition creation apparatus including:

an acquisition section that acquires a coincidence point on the second color space corresponding via the color conversion to a predetermined representative reference lattice point, among reference lattice points each having a predetermined reference coordinate component out of plural coordinate components, among plural lattice points arranged regularly in the first color space and having any of the plural coordinate components along a predetermined coordinate axis;

a calculation section that calculates coincidence points on the second color space corresponding via the color conversion to other reference lattice points each having the same reference coordinate component as the reference coordinate component of the representative reference lattice point to which the coincidence point acquired by the acquisition section corresponds, based on correspondence between the coincidence point acquired by the acquisition section and the representative reference lattice point to which the coincidence point corresponds; and

an interpolation section that calculates coincidence points on the second color space corresponding via the color conversion to other lattice points except for the reference lattice points among the lattice points, by interpolation based on correspondence between the reference lattice point and the coincidence point corresponding to the reference lattice point.

With the storage medium storing the color conversion definition creation program of the invention, the color conversion definition creation apparatus that creates the color conversion definition at high precision can be easily created by suppressing the number of color patches of colorimetry object.

Only the basic feature of the storage medium storing the color conversion definition creation program of the invention is described above to simply avoid duplication. However, the storage medium storing the color conversion definition creation program of the invention includes features corresponding to the above-described additional various preferable features of the color conversion definition creation apparatus, besides the basic feature.

Moreover, for the components such as the acquisition section that the color conversion definition creation program of the invention implements on the computer, one component may be implemented by one program module, or one component may be implemented by plural program modules. Also, these components may be implemented by the color conversion definition creation program alone, or may be implemented by another program or program modules according to in instruction given by the color conversion definition creation program.

As described above, according to the present invention, there can be obtained the color conversion definition creation apparatus that can create the color conversion definition at high precision by suppressing the number of color patches of colorimetry object, and the storage medium storing the color conversion definition creation program that causes the computer to operate as the color conversion definition creation apparatus.

### BRIEF DESCRIPTION OF THE DRAWINGS

FIG. 1 is an overall configuration diagram of a printing system to which one embodiment of the present invention is applied;

FIG. 2 is a block diagram showing the relationship between a color conversion apparatus and a color conversion definition creation apparatus;

FIG. 3 is an appearance perspective view of a personal computer 100 and a spectro-colorimeter 40;

FIG. 4 is a hardware configuration diagram of the personal computer 100;

FIG. 5 is a schematic diagram showing an embodiment of the storage medium storing a color conversion definition creation program according to the invention;

FIG. 6 is a block diagram showing an embodiment of the color conversion definition creation apparatus according to the invention, which is shown as one block in FIG. 2;

FIG. 7 is a schematic diagram showing the interpolation performed by an interpolation section 340;

FIG. 8 is an explanatory view for explaining the nonlinear calculation by a nonlinear calculation section 330;

FIG. 9 is a graph showing the change in average color difference with respect to the change in patch number for two kinds of color conversion definition creation apparatus; and

FIG. 10 is a graph showing the change in percentage of test lattice points with color difference of 2 or less with respect to the change in patch number for two kinds of color conversion definition creation apparatus.

### DETAILED DESCRIPTION OF THE INVENTION

Embodiments of the present invention will be described below with reference to the drawings.

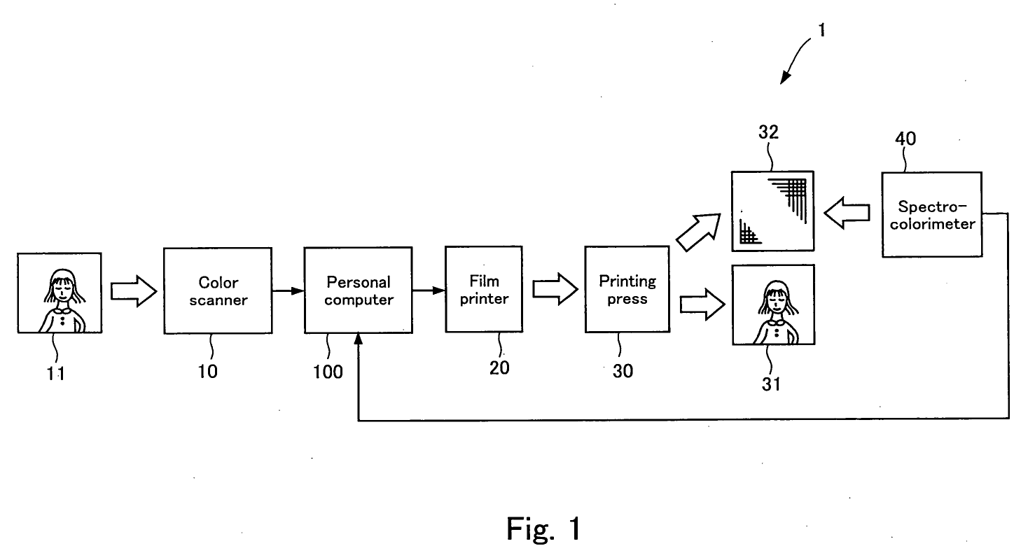

FIG. 1 is an overall configuration diagram of a printing system to which one embodiment of the invention is applied.

The printing system 1 as shown in FIG. 1 has a printing press 30 that can use process color inks of four CMYK colors and two special color inks of R and G colors other than the process colors, in which an image for printing edited based on an original image 11 is printed on a sheet of paper by the printing press 30 to produce a printed matter 31.

Herein, in this printing system 1, the special color inks in the printing press 30 can be selectively used by user's manipulation on a personal computer 100. In the following, it is presupposed that the special colors are used in the printing press 30 to simplify the description.

A color scanner 10 scans the original image 11 to generate color separation image data representing the read original image 11. This color separation image data is inputted into the personal computer 100. In the personal computer 100, the electronic stripping is made based on the input color separation image data by the user to edit the original image for printing. Herein, the editing on the personal computer 100 is performed on a color monitor for three colors of RGB to generate image data (hereinafter referred to as RGB image data) representing the original image for printing in three colors of RGB.

Herein, this personal computer 100 has a function of operating as a color conversion apparatus that converts RGB image data of RGB colors into image data represented in six colors of CMYKRG (hereinafter referred to as CMYKRG image data). With this function of the personal computer 100, the RGB image data representing the original image for printing is converted into the CMYKRG image data.

Further, this personal computer 100 has also a function of operating as a so-called RIP (Raster Image Processor). With this function, the CMYKRG image data is converted into dot image data representing the dot image in which the image is composed of dots. This conversion into the dot image data is made for each of six colors of CMYKRG to produce the dot image data for a form plate of each color.

These dot image data are inputted into a film printer 20. In the film printer 20, the film original plate for printing for each form plate corresponding to the input dot image data is produced. A press plate for each form plate is produced from the film original plate for printing, and those press plates are mounted on the printing press 30. And the ink of color corresponding to the form plate is applied on the press plate for each form plate, and the applied ink is transferred onto the printing paper. The transfer is made for each form plate to form the printed matter 31.

Herein, a color conversion definition defining the color conversion between an RGB color space representing three colors of RGB and a CMYKRG color space representing six colors of CMYKRG is used in the color conversion between the RGB image data and the CMYKRG image data. The personal computer 100 also has a function of operating as an embodiment of the color conversion definition creation apparatus according to the invention to create the color conversion definition. In this embodiment, the color conversion definition created by the color conversion definition creation apparatus is used in the color conversion apparatus to execute the color conversion. In creating the color conversion definition, the personal computer 100 outputs chart data representing a color chart 32 in which plural color patches are arranged into the film printer 20 prior to the creation. And the color chart 32 is printed in accordance with the chart data, thereby the colors of the color patches making up the color chart 32 are measured by a spectro-colorimeter 40. The colorimetry results of the spectro-colorimeter 40 are inputted into the personal computer 100, and used for creating the color conversion definition, as will be described later.

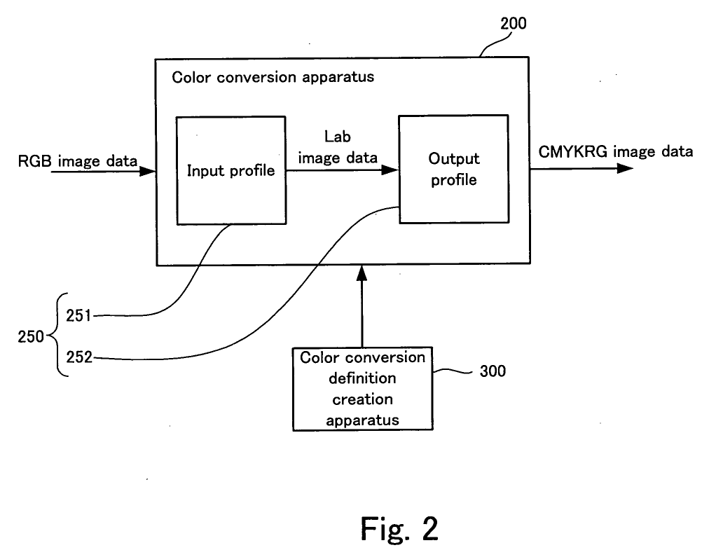

FIG. 2 is a block diagram showing the relationship between the color conversion apparatus and the color conversion definition creation apparatus.

In FIG. 2, a color conversion apparatus 200 that performs the color conversion between the RGB image data and the CMYKRG image data and a color conversion definition creation apparatus 300 that creates the color conversion definition 250 for use in the color conversion are schematically shown.

Herein, it is easy for humans to understand the color conversion between the RGB image data and the CMYKRG image data, namely, the RGB color space depending on the color scanner 10 and the CMYKRG color space depending on both the film printer 20 and the printing press 30, if the conversion is performed via an Lab color space that is one example of the common color space not dependent on the color scanner 10, the film printer 20 and the printing press 30. Also, it is easy for humans to understand a color conversion definition 250 for use in the color conversion with the color conversion apparatus 200, if the definition 250 is considered as one in which an input profile 251 defining the color conversion between the RGB color space depending on the color scanner 10 serving as the input device and the Lab color space is combined with, via the Lab color space, an output profile 252 defining the color conversion between the CMYKRG color space depending on the film printer 20 and the printing press 30 serving as the output devices and the Lab color space as shown in FIG. 2. Therefore, in this embodiment, the color conversion definition creation apparatus 300 creates the color conversion definition 250 by acquiring the input profile 251 and the output profile 252 and combining them via the Lab color space.

Herein, in this embodiment, a scanner profile, which is provided from the manufacturer of the color scanner 10, is employed as the input profile 251. As a result, the color conversion definition creation apparatus 300 creates the color conversion definition 250 by substantially creating the output profile 252. This output profile 252 is an example of the color conversion definition according to the invention.

This color conversion definition creation apparatus 300 is implemented on the personal computer 100 shown in FIG. 1 that operates in accordance with an example of the color conversion definition creation program according to the invention described later.

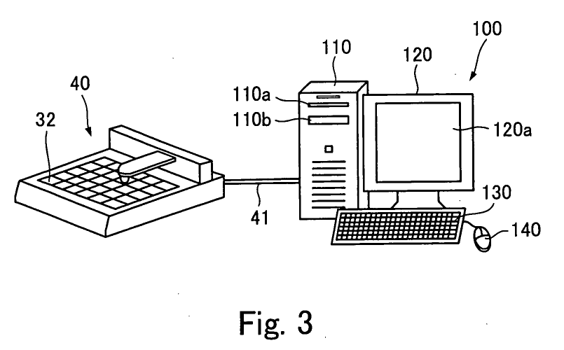

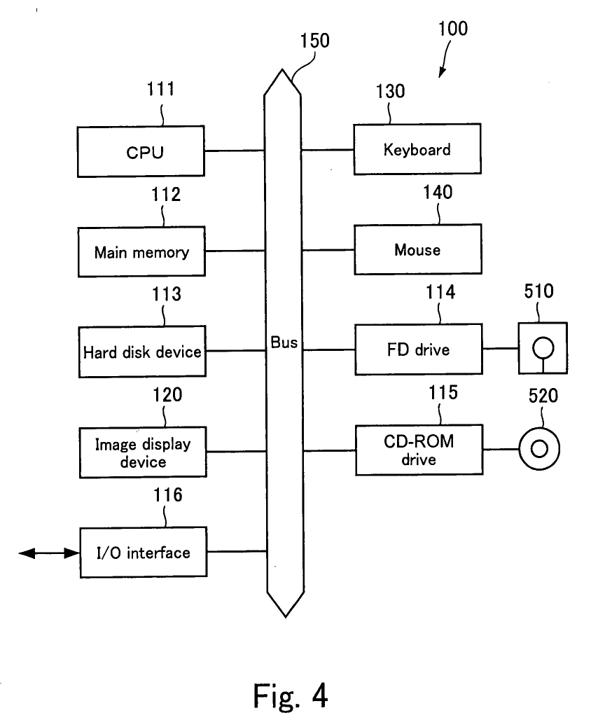

FIG. 3 is an appearance perspective view of the personal computer 100 and the spectro-colorimeter 40, and FIG. 4 is a hardware configuration diagram of the personal computer 100.

The spectro-colorimeter 40 as shown in FIG. 3 is loaded with the color chart 32 by the operator. This color chart 32 has plural color patches arranged, in which for each of the color patches, the calorimetric value is obtained in XYZ value by the spectro-colorimeter 40. The XYZ value of each color patch obtained by colorimetry with the spectro-colorimeter 40 is inputted into the personal computer 100 via a cable 41.

This color chart 32 is printed by the printing system 1 as shown in FIG. 1. In the personal computer 100, the output profile 252 (see FIG. 2) is created based on the XYZ value obtained for each color patch of the color chart 32. The detailed description about the creation of the output profile 252 will be described later, and the hardware configuration of the personal computer 100 will be described below.

This personal computer 100 includes, in appearance, a main device 110, an image display device 120 for displaying an image on a display screen 120a in accordance with an instruction from the main device 110, a keyboard 130 for inputting various kinds of information to the main device 110 in accordance with key operation and a mouse 140 for designating any position on the display screen 120a and inputting an instruction in accordance with an icon, for example, displayed at that position. This main device 110 has, in appearance, an FD loading port 110a for loading a flexible disk (hereinafter abbreviated as FD) and a CD-ROM loading port 110b for loading a CD-ROM.

As shown in FIG. 4, the main device 1.10 internally includes a CPU 111 for executing various programs, a main memory 112 for reading and expanding a program stored in a hard disk device 113 for execution by the CPU 111, the hard disk device 113 storing various programs and data, an FD drive 114 for making access to an FD 510, a CD-ROM drive 115, loaded with a CD-ROM 520, for making access to the loaded CD-ROM 520, and an I/O interface 116, connected to the color scanner 10 or film printer 20 of FIG. 1, for exchanging data with these devices. These components are interconnected via a bus 150 with the image display device 120, the keyboard 130 and the mouse 140 shown in FIG. 3.

In this embodiment, the CD-ROM 520 as shown in FIG. 3 is an embodiment of the storage medium storing the color conversion definition creation program according to the invention, which causes the personal computer 100 to operate as the color conversion definition creation apparatus 300 that is an embodiment of the color conversion definition creation apparatus of the invention. And if the CD-ROM 520 is loaded into the CD-ROM drive 115, the program stored in the CD-ROM 520 is uploaded into the personal computer 100 and written into the hard disk device 113. Thereby, the personal computer 100 operates as the color conversion definition creation apparatus 300.

Now, the color conversion definition creation program of the invention will be described below.

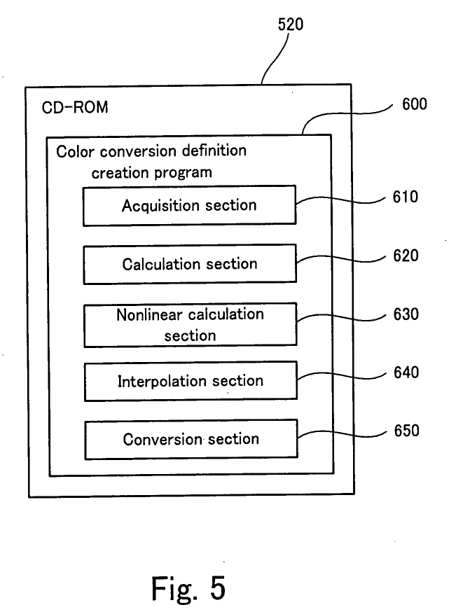

FIG. 5 is a schematic diagram showing the embodiment of the storage medium storing the color conversion definition creation program according to the invention.

In FIG. 5, the CD-ROM 520 that is the embodiment of the storage medium storing the color conversion definition creation program of the invention is schematically shown, in which a color conversion definition creation program 600 is stored.

This color conversion definition creation program 600 causes the computer 100 to operate as the embodiment of the color conversion definition creation apparatus of the invention, and has an acquisition section 610, a calculation section 620, a nonlinear calculation section 630, an interpolation section 640 and a conversion section 650. The details of each element of this color conversion definition creation program 600 will be described later.

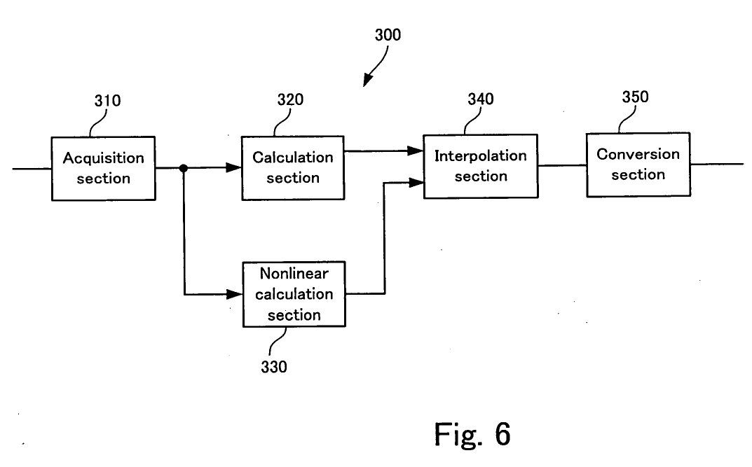

FIG. 6 is a block diagram showing the embodiment of the color conversion definition creation apparatus of the invention, which is shown as one block in FIG. 2.

The color conversion definition creation apparatus 300 that is the embodiment of the color conversion definition creation apparatus of the invention as shown in FIG. 6 is activated by installing and executing the color conversion definition creation program 600 of FIG. 5 on the computer 100 of FIG. 1. The color conversion definition creation apparatus 300 includes an acquisition section 310, a calculation section 320, a nonlinear calculation section 330, an interpolation section 340 and a conversion section 350.

If the color conversion definition creation program 600 of FIG. 5 is installed onto the computer 100 of FIG. 1, the acquisition section 610, the calculation section 620, the nonlinear calculation section 630, the interpolation section 640 and the conversion section 650 of the color conversion definition creation program 600 implement the acquisition section 310, the calculation section 320, the nonlinear calculation section 330, the interpolation section 340 and the conversion section 350 of the color conversion definition creation apparatus 300 shown in FIG. 6, respectively. Herein, each element of the color conversion definition creation apparatus 300 is implemented by a combination of the hardware of the computer and the OS and application program executed on the computer, whereas each element of the color conversion definition creation program 600 of FIG. 5 is implemented only by the application program.

Also, the acquisition section 310, the calculation section 320, the nonlinear calculation section 330, the interpolation section 340 and the conversion section 350 of the color conversion definition creation apparatus 300 are examples of the acquisition section, the calculation section, the nonlinear calculation section, the interpolation section and the conversion section of the color conversion definition creation apparatus according to the invention, respectively.

In the following, description of each element of the color conversion definition creation apparatus 300 as shown in FIG. 6 will be provided below, which also serves as description of the details of each element of the color conversion definition creation program as shown in FIG. 5.

Herein, the output profile 252 (see FIG. 2) created by the color conversion definition creation apparatus 300 will be additionally described below.

This output profile 252 describes one-to-one pairs of each of plural lattice points arranged regularly within the CMYKRG color space that is the six-dimensional device color space depending on the film printer 20 and the printing press 30 of FIG. 1 and each of plural coincidence points corresponding to the lattice points on the Lab color space via the color conversion in a table format.

Herein, in this embodiment, the plural lattice points are the coordinate points within the CMYKRG color space as follows. That is, the plural lattice points are 6⁶=46656 coordinate points represented by combining six kinds of coordinate components on the C-axis (C values: dot percent=0%, 20%, 40%, 60%, 80%, 100%), six kinds of coordinate components on the M-axis (M values=0%, 20%, 40%, 60%, 80%, 100%), six kinds of coordinate components on the Y-axis (Y values=0%, 20%, 40%, 60%, 80%, 100%), six kinds of coordinate components on the K-axis (K values=0%, 20%, 40%, 60%, 80%, 100%), six kinds of coordinate components on the R-axis (R values=0%, 20%, 40%, 60%, 80%, 100%), and six kinds of coordinate components on the G-axis (G values=0%, 20%, 40%, 60%, 80%, 100%). The output profile 252 consists of the pairs of each of 46656 lattice points and each of 46656 coincidence points corresponding to the lattice points.

In this embodiment, first of all, the output profile made for the XYZ color space which defines the color conversion between the CMYKRG color space and the XYZ color space that is one kind of the common color space is produced. This XYZ color space corresponds to the colorimetry with the spectro-colorimeter 40 as shown in FIGS. 1 and 3, and can be converted one-to-one in the coordinate into the Lab color space. In this embodiment, the output profile made for the XYZ color space is produced, and then, the coordinate of each of the 46656 coincidence points on the XYZ color space corresponding to the lattice points in the output profile made for the XYZ color space is converted into the coordinate of the Lab color space, so that the output profile made for the XYZ color space is converted into the output profile 252 made for the Lab color space. In this embodiment, the output profile 252 as shown in FIG. 2 is obtained through this process. Herein, the CMYKRG color space is an example of the first color space according to the invention, the XYZ color space is an example of the second color space according to the invention, and the coincidence point on the XYZ color space is an example of the coincidence point according to the invention.

Herein, in this embodiment, among the six kinds of K values as above described, the four kinds of K values, 0%, 20%, 60% and 100%, are treated as the reference coordinate components. And among the 46656 lattice points within the CMYKRG color space, the lattice points having the reference coordinate components as the K value are used as the reference lattice points. Further, the lattice point selected properly from the reference lattice points is used as a representative reference lattice point. Herein, the coordinate axis corresponding to the K color is an example of the predetermined coordinate axis according to the invention, the reference coordinate component is an example of the reference coordinate component according to the invention, the reference lattice point is an example of the reference lattice point according to the invention, and the representative reference lattice point is an example of the representative reference lattice point according to the invention.

In this embodiment, prior to creation of the output profile, the color chart 32, which is composed of plural color patches whose colors are represented by plural representative reference lattice points, is printed. And each of plural color patches making up the color chart 32 is measured by the spectro-colorimeter 40 to obtain the XYZ value of each color patch.

The XYZ value of each color patch is inputted into the acquisition section 310 as shown in FIG. 6.

Herein, the XYZ value of each color patch is equivalent to the coincidence point on the XYZ color space corresponding to the representative reference lattice point via the color conversion.

Next, for each of the four kinds of reference coordinate components as described above, the calculation section 320 calculates the coincidence points on the XYZ color space corresponding via the color conversion to the reference lattice points other than the representative reference lattice points among the reference lattice points having the reference coordinate components as the K value.

The calculation of this calculation section 320 involves solving the following Laplace equation for each K value.

$$\frac{{\partial }^{2} U}{\partial {C}^{2}} + \frac{{\partial }^{2} U}{\partial {M}^{2}} + \frac{{\partial }^{2} U}{\partial {Y}^{2}} + \frac{{\partial }^{2} U}{\partial {R}^{2}} + \frac{{\partial }^{2} U}{\partial {G}^{2}} = 0 \qquad [ Formula 1 ]$$

Herein, “U” denotes a continuous function of five values, CMYRG, representing three values, XYZ on the XYZ color space.

In solving the Laplace equation for the reference coordinate component, the calculation section 320 solves the Laplace equation by a finite difference method in which the pair of the representative reference lattice point having the reference coordinate component as the K value and the XYZ value obtained by colorimetry for the color patch having the color represented by the representative reference lattice point is set as the boundary condition. Since the finite difference method for this Laplace equation is well known, the detailed description is omitted here.

By this calculation in the calculation section 320, the coincidence point corresponding to the reference lattice point having each of the four kinds of reference coordinate components as the K value is obtained.

Next, in the interpolation section 340, the coincidence points corresponding to other lattice points except for the reference lattice points are obtained by the interpolation based on the correspondence between the reference lattice points and the coincidence points corresponding to the reference points.

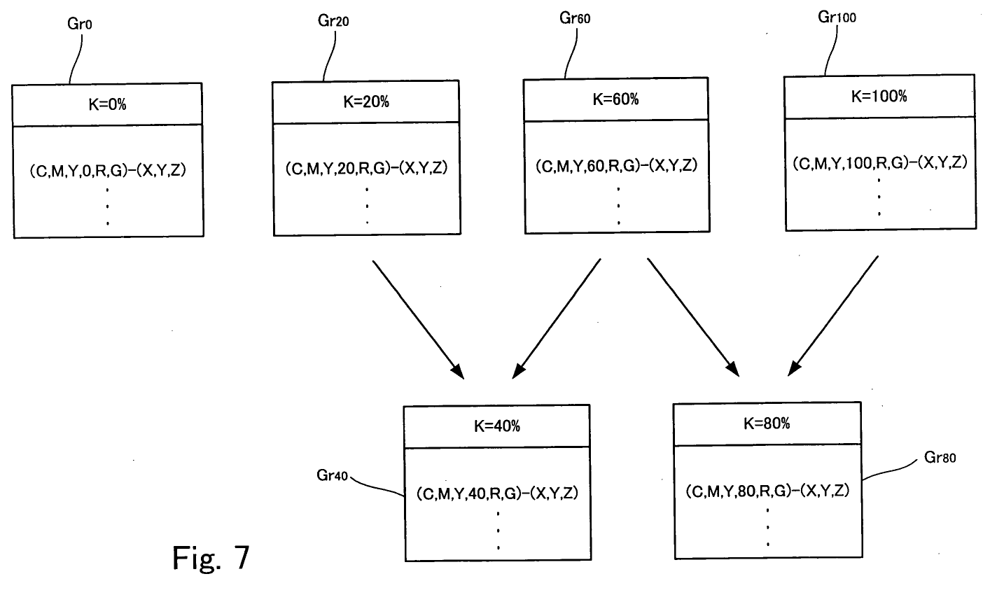

FIG. 7 is a schematic diagram showing the interpolation performed by the interpolation section 340.

By the above calculation of the calculation section 320, four kinds of sets Gr₀, Gr₂₀, Gr₆₀, and Gr₁₀₀ of coincidence points corresponding to the reference lattice points having each of the four kinds of reference coordinate components (K values=0%, 20%, 60%, 100%) for K value among the 46656 lattice points are obtained. In the interpolation section 340, two kinds of sets Gr₄₀ and Gr₈₀ of coincidence points corresponding to the lattice points other than the reference lattice points having two kinds of coordinate components (K value=40%, 80%) for K value are obtained.

At this time, the coincidence point corresponding to the lattice point having the K value of 40% is obtained by interpolation with the coincidence points corresponding to two points of the reference lattice point having the K value of 20% and the reference lattice point having the K value of 60%, which lie directly across the lattice point in the K axis direction in the CMYKRG color space, as shown in FIG. 7. For example, the coincidence point (X, Y, Z) corresponding to the lattice point of (C, M, Y, K, R, G)=(20, 20, 0, 40, 0, 60) having the K value of 40% is obtained by interpolation with the coincidence point (X, Y, Z) corresponding to the reference lattice point of (C, M, Y, K, R, G)=(20, 20, 0, 20, 0, 60) having the K value of 20% and the coincidence point (X, Y, Z) corresponding to the reference lattice point of (C, M, Y, K, R, G)=(20, 20, 0, 60, 0, 60) having the K value of 60%. Such interpolation is made for all the lattice points having the K value of 40% other than the reference lattice points. Similarly, the coincidence point corresponding to the lattice point having the K value of 80% is obtained by interpolation with the coincidence points corresponding to two points of the reference lattice point having the K value of 60% and the reference lattice point having the K value of 100%, which lie directly across the lattice point in the K axis direction in the CMYKRG color space. This interpolation is made for all the lattice points having the K value of 80% other than the reference lattice points.

Herein, in this embodiment, the interpolation performed by the interpolation section 340 of FIG. 6 is the nonlinear interpolation in consideration of the non-linearity of dot gain in the printing press as follows.

Assuming that the coincidence point of interpolation object is (X, Y, Z), and two coincidence points corresponding to two reference lattice points which lie directly across the lattice point corresponding to the coincidence point in the K axis direction are (X₋₁, Y₋₁, Z₋₁) and (X₊₁, Y₊₁, Z₊₁), the coincidence point (X, Y, Z) of interpolation object is obtained in accordance with the following interpolation formula.

(X, Y, Z)=W₋₁×(X₋₁, Y₋₁, Z₋₁)+W₊₁×(X₊₁, Y₊₁, Z₊₁)

Where two coefficients W₋₁ and W₊₁ in this interpolation formula are weights of interpolation, which represent the non-linearity in this interpolation.

In the color conversion definition creation apparatus 300 of this embodiment, the nonlinear calculation section 330 calculates two coefficients representing the non-linearity of this interpolation. The calculation of the non-linearity in this nonlinear calculation section 330 is made based on the Y value of the XYZ values acquired for each of four color patches with K single color, of which colors are represented by four representative reference lattice points with K single color, (C, M, Y, K, R, G)=(0, 0, 0, 0, 0, 0), (0, 0, 0, 20, 0, 0), (0, 0, 0, 60, 0, 0) and (0, 0, 0, 100, 0, 0), among plural color patches making up the color chart 32, acquired by the acquisition section 310.

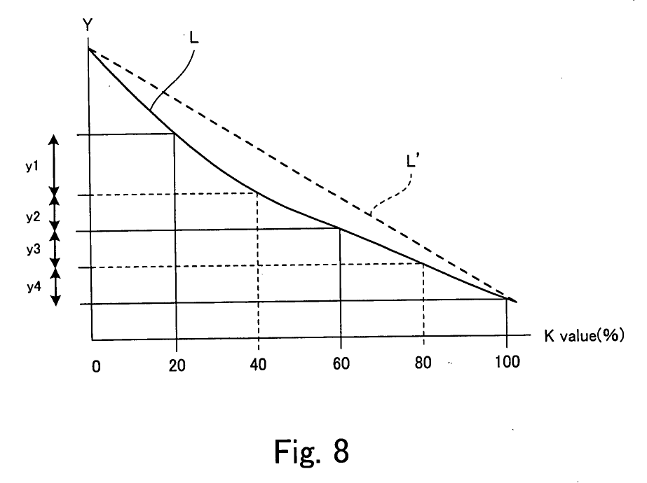

FIG. 8 is an explanatory view for explaining the nonlinear calculation by the nonlinear calculation section 330.

In FIG. 8, a graph representing the correspondence between K value and Y value for four representative reference lattice points is shown. In the case where there is no dot gain in the printing press 30 as shown in FIG. 1, the correspondence between both is linear as indicated by the straight line L′ drawn in the dotted line. However, actually, the correspondence between both is nonlinear as indicated by the curve L drawn in the solid line owing to this dot gain.

In the nonlinear calculation section 330 of FIG. 6, first of all, the curve L indicating the correspondence between both is approximately obtained from the K value and the Y value for each of four representative reference lattice points. And from this curve L, a different y1 between Y value when K value=20% and Y value when K value=40%, a different y2 between Y value when K value=40% and Y value when K value=60%, a different y3 between Y value when K value=60% and Y value when K value=80%, and a different y4 between Y value when K value=80% and Y value when K value=100% are calculated. Moreover, from these differences, two coefficients W₋₁ and W₊₁ in the above interpolation formula are calculated in the following manner in the case where the coincidence point is obtained for the lattice point having the K value of 40% and in the case where the coincidence point is obtained for the lattice point having the K value of 80%. Assuming that two coefficients are W40₋₁ and W40₊₁ in the former case, and two coefficients are W80₋₁ and W80₊₁ in the latter case, these coefficients are obtained in accordance with the following formulas.

W40₋₁=(y2)/(y1+y2)

W40₊₁=(y1)/(y1+y2)

W80₋₁=(y4)/(y3+y4)

W80₊₁=(y3)/(y3+y4)

The coefficients obtained in this manner by the nonlinear calculation section 330 of FIG. 6 are passed to the interpolation section 340. And the coincidence points corresponding to the lattice points other than the reference lattice points having two kinds of coordinate components (K value=40%, 80%) for K value are obtained by interpolation using the interpolation formula into which each coefficient is substituted.

When the interpolation in this interpolation section 340 is ended, the coincidence points on the XYZ color space corresponding to all the 46656 lattice points within the CMYKRG color space via the color conversion are obtained.

In this embodiment, in the conversion section 350, the coincidence points on the XYZ color space are converted into the coincidence points on the Lab color space where it is easy for humans to image the colors. And the pair of each of the 46656 lattice points and each of the 46656 coincidence points on the Lab color space corresponding to the lattice points obtained by this conversion is collected in a table format to complete the output profile 252 as shown in FIG. 2.

With the color conversion definition creation apparatus 300 of this embodiment as described above, the coincidence points corresponding to the reference lattice points having the K value of 0%, 20%, 60% and 100%, but not all the 46656 coincidence points, are calculated by using the calorimetric value obtained by colorimetry of the color patch as a clue. And the remaining coincidence points are obtained by the interpolation by using a result of the calculation result as a clue. In this two-stage process, the coincidence points obtained through the former half process have higher precision than the coincidence points obtained where all the coincidence points are calculated at a time, because there are a smaller number of calculation objects. Further, the remaining coincidence points are obtained by the interpolation using the coincidence points calculated at high precision as a clue, thereby the remaining coincidence points have higher precision than the coincidence points obtained where all the coincidence points are calculated at a time. In this manner, according to this embodiment, if the number of clues is the same, all the coincidence points are obtained at higher precision than where all the coincidence points are calculated at a time. In the case where all the coincidence points are calculated at a time, more clues (calorimetric values of many color patches) are needed to obtain all the coincidence points at high precision, but in this embodiment, all the coincidence points can be obtained at high precision, based on a smaller number of clues. That is, in this embodiment, through the two-stage process in which some of the points are calculated at high precision and the remaining points are obtained by the interpolation, all the coincidence points corresponding to all the plural lattice points can be obtained at high precision, based on a smaller number of color patches.

An experiment was conducted for confirming the effects in this embodiment.

In this experiment, the color conversion definition creation apparatus 300 of this embodiment that acquires the coincidence points by the calculation using the Laplace equation and the interpolation, and another color conversion definition creation apparatus that acquires the coincidence points by only the calculation using the Laplace equation are employed. First of all, the test color patches with the colors represented by predetermined test lattice points among the 46656 lattice points are printed by the printing press, and the color of each color patch is measured. On the other hand, each of two kinds of color conversion definition creation apparatus creates the output profile. And in the created output profile, a color difference between the Lab value of the coincidence point corresponding to the test lattice point and the Lab value obtained by colorimetry of the test color patch is obtained. And the average color difference for all the test lattice points and the percentage of the test lattice points with the color difference of 2 or less to the all the test lattice points are obtained. The above process is performed by changing the number of test color patches variously.

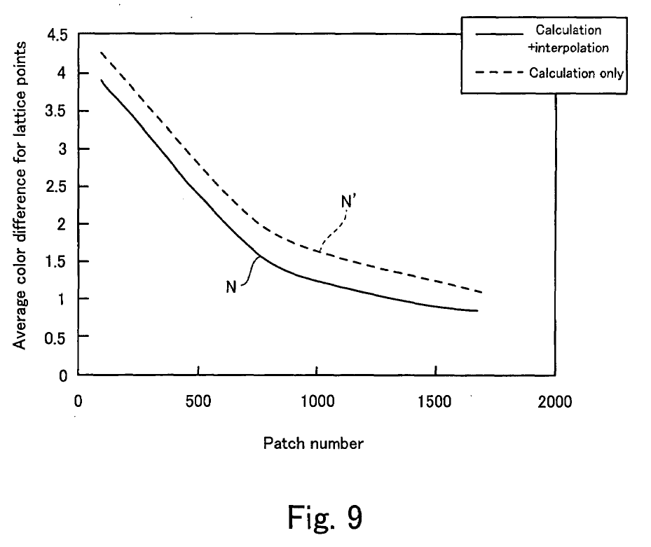

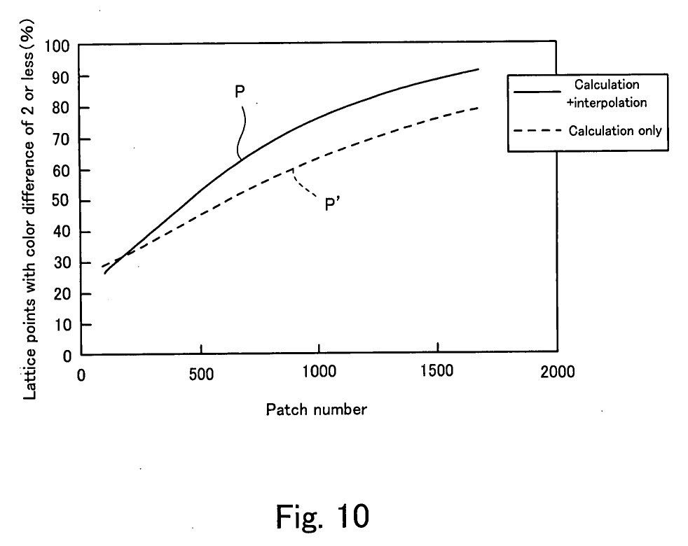

FIG. 9 is a graph showing the change in average color difference with respect to the change in patch number for two kinds of color conversion definition creation apparatus. FIG. 10 is a graph showing the change in percentage of test lattice points with color difference of 2 or less with respect to the change in patch number for two kinds of color conversion definition creation apparatus.

In FIG. 9, the change in the average color difference is indicated by the solid line N for the color conversion definition creation apparatus 300 of this embodiment that acquires the coincidence points by the calculation using the Laplace equation and the interpolation, and by the dotted line N′ for another color conversion definition creation apparatus that acquires the coincidence points by only the calculation using the Laplace equation. Also, in FIG. 10, the change in the percentage of the test lattice points with color difference of 2 or less is indicated by the solid line P for the color conversion definition creation apparatus 300 of this embodiment, and by the dotted line P′ for another color conversion definition creation apparatus.

For the average color difference, the precision of the created output profile is higher at the smaller value. For the percentage of test lattice points with the color difference of 2 or less, the precision of the output profile is higher at greater percentage. From FIGS. 9 and 10, it will be found that as the number of color patches of colorimetry object is larger, the precision of the output profile is higher for two kinds of color conversion definition creation apparatus as described above. Further, if the number of patches is the same, the color conversion definition creation apparatus 300 of this embodiment can create the output profile at higher precision than another color conversion definition creation apparatus. For the output profile having the same precision, the color conversion definition creation apparatus 300 of this embodiment can create the output file with a smaller number of patches than another color conversion definition creation apparatus, as seen from FIGS. 9 and 10.

In this manner, with the color conversion definition creation apparatus 300 of this embodiment, the color conversion definition at high precision can be created by suppressing the number of color patches of colorimetry object.

In the above description, as one embodiment of the color conversion definition creation apparatus of the invention, the color conversion definition creation apparatus 300 that creates the output profile 252 made for the printing press 30 for printing using two special colors is illustrated, but the invention is not limited thereto. The color conversion definition creation apparatus of the invention may create the output profile made for the printing press that performs printing using only the process colors such as three colors of CMY or four colors of CMYK, printing using only one special color, or printing using three or more special colors. The color conversion definition creation apparatus of the invention may also create the output profile made for the output device other than the printing press such as a printer for performing color printing, or a color monitor for displaying a color image, or may create the input profile made for the input device such as a scanner for scanning a manuscript to obtain image data or a DSC (digital still camera) for producing image data by taking a picture of a subject.

Also, in the above description, as one embodiment of the color conversion definition creation apparatus of the invention, the color conversion definition creation apparatus 300 that creates the output profile 252 in which the XYZ color space is firstly used as the common color space, then the coordinate conversion is made between the XYZ color space and the Lab color space and finally the Lab color space is used as the common color space is illustrated, but the invention is not limited thereto. The color conversion definition creation apparatus of the invention may create the output profile using the Lab color space from the beginning as the common color space, or may create the output profile using the XYZ color space as the common color space without making the coordinate conversion.

Also, in the above description, as one example of the predetermined coordinate axis according to the invention, the coordinate axis corresponding to the K color in the CMYKRG color space is illustrated, but the invention is not limited thereto. The predetermined coordinate axis of the invention may be the coordinate axis corresponding to the color other than the K color in the CMYKRG color space.

Also, in the above description, as one example of the lattice point according to the invention, the lattice point having six kinds of coordinate components of 0%, 20%, 40%, 60%, 80% and 100% for each coordinate axis is illustrated, but the invention is not limited thereto. The lattice point according to the invention may have the coordinate component other than the six kinds.

Also, in the above description, as the reference coordinate component according to the invention, all the coordinate components (six in this embodiment), except for two coordinate components, that the lattice point can have on the predetermined coordinate axis (K axis in this embodiment) are illustrated, but the invention is not limited thereto. The reference coordinate component according to the invention may be all the coordinate components that the lattice point can have on the predetermined coordinate axis, except for one or three or more coordinate components.

Also, in the above description, as one example of the interpolation section according to the invention, the interpolation section 340 that makes the nonlinear interpolation is illustrated, but the invention is not limited thereto. The interpolation section of the invention may make the linear interpolation, for example.

Also, in the above description, as one example of the interpolation section according to the invention, the interpolation section 340 that makes the nonlinear interpolation by being given the non-linearity of interpolation calculated based on the calorimetric value obtained by colorimetry of the color patch is illustrated, but the invention is not limited thereto. The interpolation section of the invention may be given the non-linearity obtained beforehand externally.

Also, in the above description, as one example of the interpolation section according to the invention, the interpolation section 340 that obtains the coincidence point of interpolation object by the interpolation using the coincidence points for the two reference lattice points which lie directly across the lattice point corresponding to the coincidence point in the K axis direction is illustrated, but the invention is not limited thereto. The interpolation section of the invention may make the interpolation using the coincidence points for the two reference lattice points which lie across the lattice point corresponding to the coincidence point of interpolation object with a small distance in the K axis direction, or may make the interpolation using the coincidence points for the two reference lattice points located at both ends of the array among the reference lattice points arranged on the straight line in the K axis direction passing through the lattice point corresponding to the coincidence point of interpolation object.

What is claimed is:

1. A color conversion definition creation apparatus that creates a color conversion definition defining a color conversion between a first color space and a second color space, comprising:
an acquisition section that acquires a coincidence point on the second color space corresponding via the color conversion to a predetermined representative reference lattice point, among reference lattice points each having a predetermined reference coordinate component out of plural coordinate components, among plural lattice points arranged regularly in the first color space and having any of the plural coordinate components along a predetermined coordinate axis;
a calculation section that calculates coincidence points on the second color space corresponding via the color conversion to other reference lattice points each having the same reference coordinate component as the reference coordinate component of the representative reference lattice point to which the coincidence point acquired by the acquisition section corresponds, based on correspondence between the coincidence point acquired by the acquisition section and the representative reference lattice point to which the coincidence point corresponds; and
an interpolation section that calculates coincidence points on the second color space corresponding via the color conversion to other lattice points except for the reference lattice points among the lattice points, by interpolation based on correspondence between the reference lattice point and the coincidence point corresponding to the reference lattice point.

2. The color conversion definition creation apparatus according to claim 1, wherein the calculation section calculates the coincidence point corresponding to the reference lattice point by solving a Laplace equation stipulating systematically a correlation between the reference lattice points and the coincidence points corresponding to the reference lattice points, by using the correspondence between the coincidence point acquired by the acquisition section and the representative reference lattice point to which the coincidence point corresponds as a boundary condition.

3. The color conversion definition creation apparatus according to claim 1, wherein the interpolation section is given a non-linearity of interpolation and calculates the coincidence points corresponding to the other lattice points by nonlinear interpolation in accordance with the non-linearity.

4. The color conversion definition creation apparatus according to claim 1, wherein the first color space is a color space having a coordinate axis corresponding to K color as the predetermined coordinate axis.

5. The color conversion definition creation apparatus according to claim 1, further comprising a nonlinear calculation section that calculates a non-linearity of interpolation based on the coincidence point acquired by the acquisition section,
wherein the interpolation section is given the non-linearity calculated by the nonlinear calculation section, and calculates the coincidence points corresponding to the other lattice points by nonlinear interpolation in accordance with the non-linearity.

6. The color conversion definition creation apparatus according to claim 1, wherein the second color space is a XYZ color space, and
the color conversion definition creation apparatus further comprises a conversion section that converts the coordinates of the coincidence points on the XYZ color space corresponding to the lattice points via the color conversion defined by the color conversion definition into coordinates on a Lab color space, thereby converting the color conversion definition to a color conversion definition defining a color conversion between the first color space and the Lab color space.

7. A storage medium storing a color conversion definition creation program that is incorporated into a computer and causes the computer to operate as a color conversion definition creation apparatus that creates a color conversion definition defining a color conversion between a first color space and a second color space, the color conversion definition creation apparatus comprising:
an acquisition section that acquires a coincidence point on the second color space corresponding via the color conversion to a predetermined representative reference lattice point, among reference lattice points each having a predetermined reference coordinate component out of plural coordinate components, among plural lattice points arranged regularly in the first color space and having any of the plural coordinate components along a predetermined coordinate axis;
a calculation section that calculates coincidence points on the second color space corresponding via the color conversion to other reference lattice points each having the same reference coordinate component as the reference coordinate component of the representative reference lattice point to which the coincidence point acquired by the acquisition section corresponds, based on correspondence between the coincidence point acquired by the acquisition section and the representative reference lattice point to which the coincidence point corresponds; and
an interpolation section that calculates coincidence points on the second color space corresponding via the color conversion to other lattice points except for the reference lattice points among the lattice points, by interpolation based on correspondence between the reference lattice point and the coincidence point corresponding to the reference lattice point.
